(19) United States
(12) Patent Application Publication
(10) Pub. No.: US 2021/0050285 A1
(43) Pub. Date: Feb. 18, 2021

(54) Semiconductor Device

(71) Applicant: AOI Electronics Co., Ltd., Takamatsu-shi, Kagawa (JP)

(72) Inventor: Katsuhiro TAKAO, Marugame-shi, Kagawa (JP)

(21) Appl. No.: 17/042,264

(22) PCT Filed: Jul. 12, 2018
(86) PCT No.: PCT/JP2018/026364

§ 371 Date: Sep. 28, 2020

(30) Foreign Application Priority Data
Mar. 29, 2018 (JP) 2018-064569

(51) Int. Cl. H01L 23/495; H01L 23/31; H01L 23/00; H01L 21/48; H01L 21/56; H01L 21/78

(52) U.S. Cl. CPC H01L 23/49548; H01L 23/3114; H01L 23/49503; H01L 23/4952; H01L 24/48; H01L 21/4825; H01L 2924/30105; H01L 21/561; H01L 21/565; H01L 21/568; H01L 21/78; H01L 2224/48247; H01L 21/4839

(57) ABSTRACT

A semiconductor device includes: a semiconductor element; an element conductor having an element mounting surface on which the semiconductor element is mounted; a connection conductor that is arranged apart from the element conductor and has a connection surface on an upper part thereof; a connecting line connecting the semiconductor element and the connection surface of the connection conductor; and an encapsulation resin that encapsulates the semiconductor element, the element conductor, the connection conductor, and the connecting line, wherein: a parasitic capacitance reducing structure is provided in at least one of facing side surfaces of the element conductor and of the connection conductor, the facing side surfaces being arranged to face each other.

### TECHNICAL FIELD

The present invention relates to a semiconductor device.

### BACKGROUND ART

There is known a semiconductor device in which a first conductor having a semiconductor chip mounted thereon and a second conductor connected to the semiconductor chip by a bonding wire are spaced apart from each other and then the entire elements are entirely encapsulated with an encapsulation resin. The first conductor and the second conductor have a rectangular shape in plan view, and each of side surfaces facing each other is arranged at a position equidistant from the other conductor across the whole length of the facing side (see PTL1).

### CITATION LIST

### Patent Literature

PTL1: Japanese Laid-Open Patent Publication No. 2006-287263

### SUMMARY OF INVENTION

### Technical Problem

In the semiconductor device of PTL1, the side surfaces of the first conductor and the second conductor facing each other are arranged at positions closest to each other over the whole length of the facing surfaces, so that a parasitic capacitance between the first conductor and the second conductor increases. Therefore, when applied to a high-frequency circuit for high-speed data communication or the like, for example, deterioration and lost of circuit characteristics occur, such as impedance shift and response speed delay.

### Solution to Problem

According to a 1st aspect of the present invention, a semiconductor device, comprises: a semiconductor element; an element conductor having an element mounting surface on which the semiconductor element is mounted; a connection conductor that is arranged apart from the element conductor and has a connection surface on an upper part thereof; a connecting line connecting the semiconductor element and the connection surface of the connection conductor; and an encapsulation resin that encapsulates the semiconductor element, the element conductor, the connection conductor, and the connecting line, wherein: a parasitic capacitance reducing structure is provided in at least one of facing side surfaces of the element conductor and of the connection conductor, the facing side surfaces being arranged to face each other.

According to a 2nd aspect of the present invention, in the semiconductor device according to the 1st aspect, it is preferable that the parasitic capacitance reducing structure is provided in an upper side of at least one of the element conductor and the connection conductor.

According to a 3rd aspect of the present invention, in the semiconductor device according to the 2nd aspect, it is preferable that the parasitic capacitance reducing structure is provided in a columnar shape from the upper side to a lower surface of the at least one of the element conductor and the connection conductor.

According to a 4th aspect of the present invention, in the semiconductor device according to the 1st aspect, it is preferable that the parasitic capacitance reducing structure is a facing surface in which a facing-surface distance determined at a first position closest to the other conductor side is the smallest and a facing-surface distance at a second position different from the first position is larger than the facing-surface distance at the first position.

According to a 5th aspect of the present invention, in the semiconductor device according to the 4th aspect, it is preferable that the facing surface having the parasitic capacitance reducing structure is a planar surface or a curved surface.

According to a 6th aspect of the present invention, in the semiconductor device according to the 1st aspect, it is preferable that the parasitic capacitance reducing structure is a structure in which at least one of the element conductor and the connection conductor has a polygonal shape in plan view; and the conductor having the polygonal shape has a first facing surface closest to the other conductor side and a second facing surface other than the first facing surface, and a facing-surface distance determined by the second facing surface is larger than a facing-surface distance determined by the first facing surface.

According to a 7th aspect of the present invention, in the semiconductor device according to the 1st aspect, it is preferable that the parasitic capacitance reducing structure is a structure in which at least one of the element conductor and the connection conductor has an arc shape in plan view; and the conductor having the arc shape has a first facing surface that is closest to the other conductor side and determines the minimum facing-surface distance and a second facing surface that is different from the first facing surface, and a facing-surface distance determined by the second facing surface is larger than the minimum facing-surface distance.

According to an 8th aspect of the present invention, in the semiconductor device according to the 6th or 7th aspect, it is preferable that the parasitic capacitance reducing structure includes irregularities formed continuously in the first facing surface and the second facing surface.

According to a 9th aspect of the present invention, in the semiconductor device according to any one of the 1st to 8th aspects, it is preferable that an area of the element mounting surface of the element conductor is formed smaller than an area of the semiconductor element in plan view, and an outer peripheral side surface of the semiconductor element is located outside an outer peripheral side surface of the element mounting surface.

According to a 10th aspect of the present invention, a semiconductor device comprises: a semiconductor element; an element conductor having an element mounting surface on which the semiconductor element is mounted; a connection conductor that is arranged apart from the element conductor and has a connection surface on an upper part thereof; a connecting line connecting the semiconductor element and the connection surface of the connection conductor; an encapsulation resin that encapsulates the semiconductor element, the element conductor, the connection conductor, and the connecting line; and a parasitic capacitance reducing structure provided in a facing side surface of at least one of the element conductor and the connection conductor arranged to face each other, the facing side surface facing the other conductor, wherein: in the parasitic capacitance reducing structure, an area in a first position having a smallest facing-surface distance between a facing side surface of the one conductor and a facing side surface of the other conductor is smaller than a total area of the facing side surfaces of the one conductor.

According to an 11th aspect of the present invention, in the semiconductor device according to the 10th aspect, it is preferable that the area in the first position of the one conductor is smaller than a total area of entire facing side surfaces in a second position different from the first position.

According to a 12th aspect of the present invention, a semiconductor device comprises: a semiconductor element; an element conductor having an element mounting surface on which the semiconductor element is mounted; a connection conductor that is arranged apart from the element conductor and has a connection surface on an upper part thereof; a connecting line connecting the semiconductor element and the connection surface of the connection conductor; and an encapsulation resin that encapsulates the semiconductor element, the element conductor, the connection conductor, and the connecting line; and a groove formed in the encapsulation resin between facing side surfaces of the element conductor and the connection conductor.

According to a 13th aspect of the present invention, in the semiconductor device according to any one of the 1st to 9th aspects, it is preferable that a groove formed in the encapsulation resin between facing side surfaces of the element conductor and the connection conductor.

### Advantageous Effects of Invention

According to the present invention, a parasitic capacitance between the element conductor and the connection conductor can be reduced.

### BRIEF DESCRIPTION OF DRAWINGS

FIG. 1 shows a first embodiment of a semiconductor device according to the present invention. FIG. 1(a) is a cross-sectional view of the semiconductor device and FIG. 1(b) is a bottom view of FIG. 1(a) as viewed from below.

FIG. 2 is a view for illustrating a method of manufacturing the semiconductor device shown in FIG. 1. FIGS. 2(a) to 2(e) are cross-sectional views of members in each step.

FIG. 3 shows a second embodiment of the semiconductor device according to the present invention. FIG. 3(a) is a cross-sectional view of the semiconductor device and FIG. 3(b) is a bottom view of FIG. 3(a) as viewed from below.

FIG. 4 is a view for illustrating a method of manufacturing the semiconductor device shown in FIG. 3. FIGS. 4(a) to 4(c) are cross-sectional views of members in each step and FIG. 4(d) is an enlarged view of a region A in FIG. 4(a).

FIG. 5 shows a third embodiment of the semiconductor device according to the present invention. FIG. 5(a) is a cross-sectional view of the semiconductor device, FIG. 5(b) is a first bottom view of FIG. 5(a) as viewed from below, and FIG. 5(c) is a second bottom view of FIG. 5(a) as viewed from below.

FIG. 6 is a cross-sectional view showing a fourth embodiment of the semiconductor device according to the present invention.

FIG. 7 is a cross-sectional view showing a fifth embodiment of the semiconductor device according to the present invention.

FIG. 8 shows a sixth embodiment of the semiconductor device according to the present invention and is a bottom view of the semiconductor device as viewed from bottom surface side.

FIG. 9 shows a seventh embodiment of the semiconductor device according to the present invention and is a bottom view of the semiconductor device as viewed from below.

FIG. 10 shows an eighth embodiment of the semiconductor device according to the present invention and is a bottom view of the semiconductor device as viewed from below.

FIG. 11 shows a ninth embodiment of the semiconductor device according to the present invention and is a bottom view of the semiconductor device as viewed from below.

FIG. 12 shows a tenth embodiment of the semiconductor device according to the present invention. FIG. 12(a) is a cross-sectional view of the semiconductor device and FIG. 12(b) is a bottom view of FIG. 12(a) as viewed from below.

### DESCRIPTION OF EMBODIMENTS

### First Embodiment

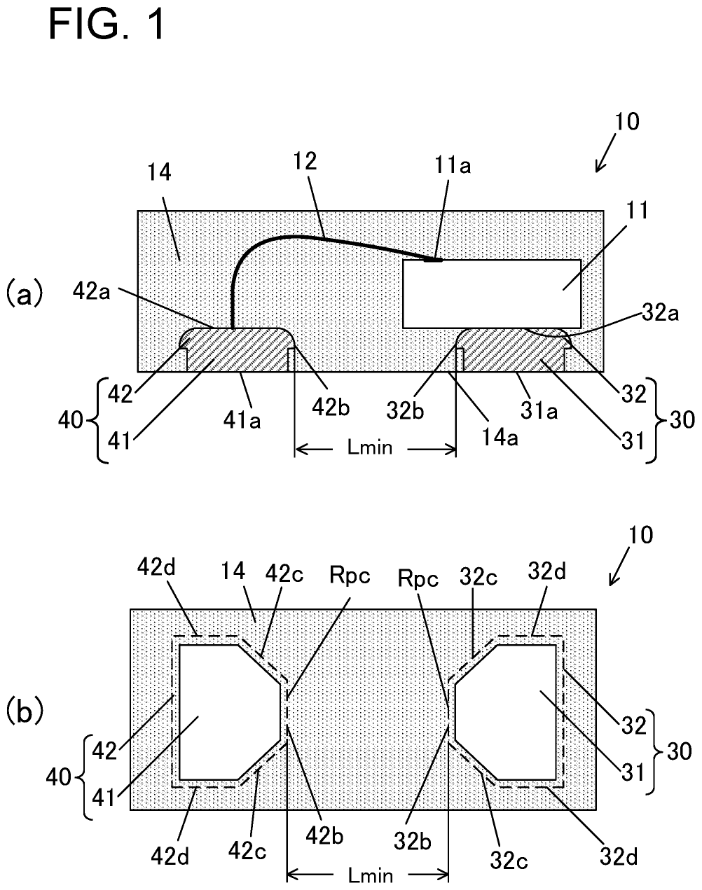

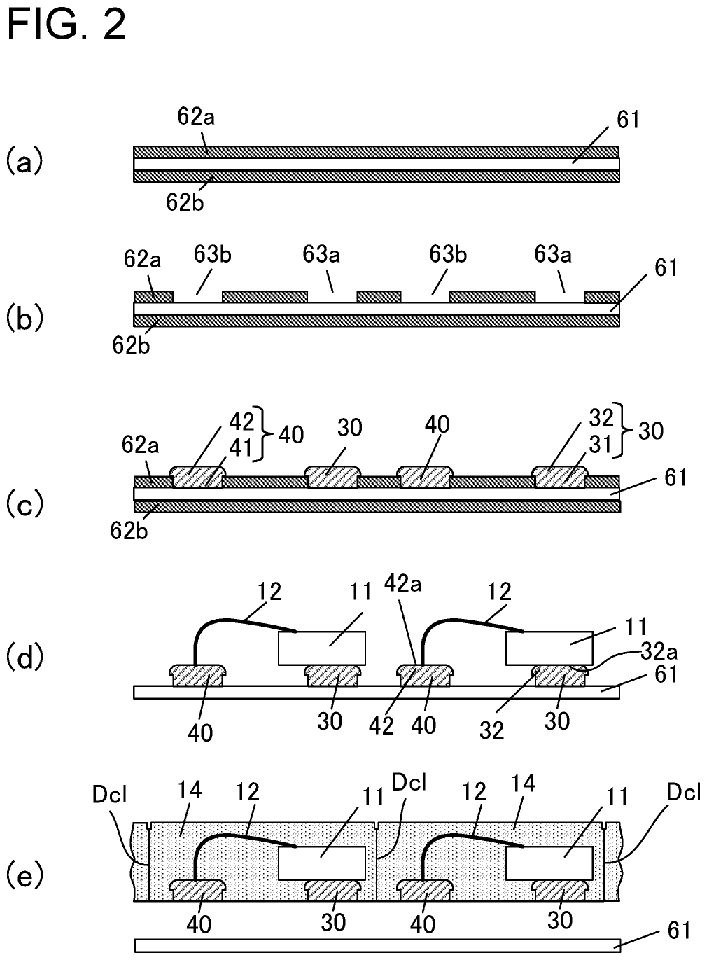

A first embodiment of a semiconductor device 10 according to the present invention will be described with reference to FIGS. 1 and 2.

FIG. 1 shows the first embodiment of the semiconductor device according to the present invention. FIG. 1(a) is a cross-sectional view of the semiconductor device and FIG. 1(b) is a bottom view of FIG. 1(a) as viewed from below.

The semiconductor device 10 includes a semiconductor element 11, an element conductor 30 on which the semiconductor element 11 is mounted, a connection conductor 40, and a bonding wire 12 connecting an electrode pad 11a of the semiconductor element 11 and the connection conductor 40, and an encapsulation resin 14 that encapsulates the entire elements.

The semiconductor element 11 has the electrode pad 11a on its upper surface and has a generally rectangular parallelepiped shape.

The element conductor 30 is made of a conductive metal such as copper, for example, and has a columnar portion 31 and an element flange portion 32. The element flange portion 32 has a shape slightly larger than the columnar portion 31, and an outer peripheral side surface of the element flange portion 32 protrudes from an outer peripheral side surface of the columnar portion 31. As shown in FIG. 1(b), the columnar portion 31 and the element flange portion 32 have similar hexagonal shapes in plan view.

In similar to the element conductor 30, the connection conductor 40 is made of a conductive metal such as copper, for example, and has a columnar portion 41 and a connection flange portion 42 that is slightly larger than the columnar portion 41. Additionally, an outer peripheral side surface of the connection flange portion 42 protrudes from an outer peripheral side surface of the columnar portion 41, and the columnar portion 41 and the connection flange portion 42 have similar hexagonal shapes in plan view.

The element conductor 30 and the connection conductor 40 are made of plating layers formed by electroforming or the like, or made of lead frames.

As shown in FIG. 1(a), an element mounting surface 32a on which the semiconductor element 11 is mounted is provided in an upper surface of the element flange portion 32 of the element conductor 30 opposite to the columnar portion 31 side. The element mounting surface 32a is an entire region of the upper surface of the element flange portion 32. In the vertical cross section shown in FIG. 1(a), a peripheral edge of the element flange portion 32 is formed in an arc shape. A thickness (height) of the element flange portion 32 is formed smaller than a thickness (height) of the columnar portion 31.

An upper surface of the connection flange portion 42 of the connection conductor 40 opposite to the columnar portion 41 side is a bonding surface 42a to which the bonding wire 12 is connected. The bonding surface 42a is an entire region of the upper surface of the connection flange portion 42. In the vertical cross section shown in FIG. 1(a), a peripheral edge of the connection flange portion 42 is formed in an arc shape. A thickness (height) of the connection flange portion 42 is formed smaller than a thickness (height) of the columnar portion 41.

The thickness of the columnar portion 31 of the element conductor 30 and the thickness of the columnar portion 41 of the connection conductor 40 are substantially the same. Further, the thickness of the element flange portion 32 of the element conductor 30 and the thickness of the connection flange portion 42 of the connection conductor 40 are substantially the same. Therefore, a total thickness of the element conductor 30 and a total thickness of the connection conductor 40 are substantially the same. The total thickness of each of the element conductor 30 and the connection conductor 40 is in a range of 20 μm to 80 μm.

One end of the bonding wire 12 is bonded to the electrode pad 11a of the semiconductor element 11 and the other end of the bonding wire 12 is bonded to almost the center of the bonding surface 42a of the connection conductor 40.

As described above, a bottom surface of the semiconductor element 11 mounted on the element mounting surface 32a of the element flange portion 32 of the element conductor 30 has an area larger than an area of the element mounting surface 32a. The semiconductor element 11 is arranged so as to protrude from the outer periphery of the element mounting surface 32a of the element flange portion 32. In other words, the area of the element mounting surface 32a of the element conductor 30 is formed smaller than the area of the bottom surface of the semiconductor element 11, and an outer peripheral side surface of the semiconductor element 11 is located outside an outer peripheral side surface of the element mounting surface 32a. By setting the size of the element mounting surface 32a of the element conductor 30 smaller than the base area of the semiconductor element 11 in this way, the semiconductor device 10 can be reduced in size. However, the size of the element mounting surface 32a of the element conductor 30 may be the same as the bottom area of the semiconductor element 11 or larger than the area of the semiconductor element 11. That is, the outer peripheral side surface of the semiconductor element 11 may be flush with the outer peripheral side surface of the element mounting surface 32a of the element conductor 30. Alternatively, the outer peripheral side surface of the semiconductor element 11 may be located inside the outer peripheral side surface of the element mounting surface 32a of the element conductor 30.

The encapsulation resin 14 encapsulates the element conductor 30, the connection conductor 40, the semiconductor element 11, and the bonding wire 12. However, a lower surface 31a of the columnar portion 31 of the element conductor 30 opposite to the element flange portion 32, and a lower surface 41a of the columnar portion 41 of the connection conductor 40 opposite to the connection flange portion 42 are substantially flush with a lower surface 14a of the encapsulation resin 14 so that the lower surfaces 31a, 41a are exposed from the lower surface 14a of the encapsulation resin 14.

The encapsulation resin 14 may be made of epoxy resin, for example. Note that the encapsulation resin is preferably made of a material having a low dielectric constant Low k, such as an epoxy resin having a relative permittivity (Dk) of 3.5 or less at a frequency of 1 to 10 GHz and a dielectric loss tangent (Df) of 0.01 or less at a frequency of 1 to 10 GHz.

As shown in FIG. 1(b), a side surface of the element flange portion 32 of the element conductor 30 facing the connection conductor 40 has a tapered polygonal shape, having a front end surface 32b and inclined surfaces 32c arranged on both sides of the front end surface 32b, in top view. Each of the inclined surfaces 32c on both sides of the front end surface 32b of the element flange portion 32 is inclined from the front end surface 32b toward a side surface 32d in a direction away from the facing connection conductor 40. Similarly, the connection flange portion 42 of the connection conductor 40 has a front end surface 42b and inclined surfaces 42c arranged on both sides of the front end surface 42b. Each of the inclined surfaces 42c on both sides of the front end surface 42b of the connection flange portion 42 is inclined from the front end surface 42b toward a side surface 42d in a direction away from the facing element conductor 30, with an increase of a distance from the front end surface 42b.

The front end surface 32b of the element flange portion 32 of the element conductor 30 and the front end surface 42b of the connection flange portion 42 of the connection conductor 40 are arranged in parallel. An inter-terminal distance between the front end surface 32b of the element flange portion 32 of the element conductor 30 and the front end surface 42b of the connection flange portion 42 of the connection conductor 40 is a minimum inter-terminal distance Lmin between the element conductor 30 and the connection conductor 40. In other words, the front end surface 32b of the element flange portion 32 of the element conductor 30 and the front end surface 42b of the connection flange portion 42 of the connection conductor 40 are the closest surfaces that are closest to their counterpart conductors.

An inter-terminal distance between the inclined surface 32c of the element flange portion 32 of the element conductor 30 and the inclined surface 42c of the connection flange portion 42 of the connection conductor 40 is equal to or more than the minimum inter-terminal distance Lmin, and the inclined surface 32c of the element flange portion 32 of the element conductor 30 and the inclined surface 42c of the connection flange portion 42 of the connection conductor 40 are arranged non-parallel to each other. Additionally, the inter-terminal distance between the columnar portion 31 of the element conductor 30 and the columnar portion 41 of the connection conductor 40 is larger than the minimum inter-terminal distance Lmin.

As described above, the area of each of the front end surface 32b of the element flange portion 32 and the front end surface 42b of the connection flange portion 42 is small, and the inclined surfaces 32c, 42c are formed on both sides of the front end surface 32b, 42b, respectively.

Thus, a parasitic capacitance between the element conductor 30 and the connection conductor 40 in the semiconductor device 10 of the above embodiment is smaller than a parasitic capacitance of a structure having no inclined surface provided in facing side surfaces of the element conductor 30 and the connection conductor 40, that is, a structure having a constant distance, i.e., the minimum inter-terminal distance Lmin between facing surfaces of the element conductor 30 and the connection conductor 40. Hereinafter, a structure having a constant distance (i.e., the minimum inter-terminal distance Lmin) between facing surfaces of the element conductor 30 and the connection conductor 40 is referred to as a comparative example.

In the semiconductor device 10 of the first embodiment, the front end surface 32b of the element flange portion 32 and the inclined surfaces 32c arranged on both sides of the front end surface 32b, which are facing side surfaces of the element conductor 30 facing the connection conductor 40, constitute a parasitic capacitance reducing structure Rpc. Similarly, the front end surface 42b and the inclined surfaces 42c arranged on both sides of the front end surface 42b of the connection flange portion 42, which are facing side surfaces of the connection conductor 40 facing the element conductor 30, constitute a parasitic capacitance reducing structure Rpc.

The area of the front end surface 32b of the element conductor 30 located at the minimum terminal distance Lmin is preferably smaller than the total area of the inclined surfaces 32c on both sides. However, it is only necessary to form the area of the front end surface 32b of the element conductor 30 smaller than the total area of the entire side surfaces facing the connection conductor 40, that is, the total areas of the front end surface 32b and the inclined surfaces 32c on both sides thereof. Similarly, the area of the front end surface 42b of the connection conductor 40 located at the minimum terminal distance Lmin is preferably smaller than the total area of the inclined surfaces 42c on both sides. However, it is only necessary to form the area of the front end surface 42b of the connection conductor 40 smaller than the total area of the entire side surfaces facing the element conductor 30, that is, the total areas of the front end surface 42b and the inclined surfaces 42c on both sides thereof

As shown in FIG. 1(a), the element flange portion 32 of the element conductor 30 projects from the columnar portion 31. Further, the connection flange portion 42 of the connection conductor 40 projects from the columnar portion 41. Therefore, the element conductor 30 and the connection conductor 40 have a structure that is difficult to be pulled out from the encapsulation resin 14 due to an anchor effect. Additionally, an inter-terminal distance, which is a distance between facing side surfaces of the columnar portion 31 of the element conductor 30 and of the columnar portion 41 of the connection conductor 40, is larger than the minimum inter-terminal distance Lmin between the front end surface 32b of the element flange portion 32 of the element conductor 30 and the front end surface 42b of the connection flange portion 42 of the connection conductor 40. Therefore, the amount of the encapsulation resin 14 filled between the terminals of the columnar portion 31 of the element conductor 30 and of the columnar portion 41 of the connection conductor 40 is increased so that occurrence of cracks of the encapsulation resin 14 in this region can be reduced.

Additionally, although not shown, the lower surface 31a of the columnar portion 31 of the element conductor 30 and the lower surface 41a of the columnar portion 41 of the connection conductor 40 are mounted by soldering to connection pads of a circuit board.

Next, one example of a method of manufacturing the semiconductor device 10 shown in FIG. 1 by electroforming will be described.

FIG. 2 is a view for illustrating the method of manufacturing the semiconductor device shown in FIG. 1. FIGS. 2(a) to 2(e) are cross-sectional views of members in each step.

As shown in FIG. 2(a), a substrate 61 is prepared, such as a stainless plate or a copper plate having a size in which the semiconductor devices 10 can be arranged in a lattice pattern. In the following description, two semiconductor devices 10 are formed. However, the manufacturing method described below may also be applied to create a large number of semiconductor devices 10 arranged in a lattice pattern.

The substrate 61 has a thickness in a range of 0.1 mm to 0.5 mm, for example. Photoresist films 62a, 62b are formed on both front and back surfaces of the substrate 61. The photoresist film 62a has a thickness corresponding to the thickness of the columnar portion 31 of the element conductor 30 and the thickness of the columnar portion 41 of the connection conductor 40. The thickness of the photoresist film 62b is not particularly limited and may be the same as the thickness of the photoresist film 62a or different from the thickness of the photoresist film 62a. The photoresist films 62a, 62b may be of positive type or negative type.

Next, as shown in FIG. 2(b), the photoresist film 62a on an upper surface side of the substrate 61 is exposed using a mask (not shown) and developed to pattern the photoresist film 62a. That is, openings 63a are formed in regions of the photoresist film 62a where the element conductors 30 are to be formed, and openings 63b are formed in regions where the connection conductors 40 are to be formed. Thereafter, the regions of the substrate 61 exposed from the photoresist film 62a are subjected to surface treatment such as oxide film removal.

Next, as shown in FIG. 2(c), the element conductor 30 and the connection conductor 40 are formed by electroforming. A plating layer formed by electroforming extends beyond the thickness of the photoresist film 62a so that a thickness of the plating layer from the surface of the photoresist film 62a is the same as the thickness of the element flange portion 32 of the element conductor 30 and the thickness of the connection flange portion 42 of the connection conductor 40. The growth of the plating layer formed on the surface of the photoresist film 62a is isotropic. Therefore, the plating layer formed over the photoresist film 62a projects to the outer peripheral side of the plating layer formed in the region of the thickness of the photoresist film 62a, and has an outer peripheral edge on the upper surface side formed in an arc shape in cross section. As a result, the element conductor 30 having the columnar portion 31 and the element flange portion 32 and the connection conductor 40 having the columnar portion 41 and the connection flange portion 42 are formed.

After forming the element conductor 30 and the connection conductor 40, the photoresist films 62a, 62b are removed.

Next, as shown in FIG. 2(d), semiconductor elements 11 are die-bonded to the element mounting surfaces 32a of the element flange portions 32 of the element conductors 30. Then, bonding wires 12 are bonded to electrode pads 11a of the semiconductor elements 11 and bonding surfaces 42a of the connection flange portions 42 of the connection conductors 40.

Next, as shown in FIG. 2(e), the encapsulation resin 14 is molded on the element conductor 30 and the connection conductor 40 side of the substrate 61 to encapsulate the entire elements. The encapsulation with the encapsulation resin 14 is performed so as to cover the entire surface in one surface side of the substrate 61 including the semiconductor element 11, the bonding wire 12, the element conductor 30, and the connection conductor 40. Then, the substrate 61 is peeled or removed from the element conductor 30 on which the semiconductor element 11 is mounted and the connection conductor 40 to which the bonding wire 12 is bonded. Thereafter, the encapsulation resin 14 is cut along dicing lines Dc1 to obtain individual semiconductor devices 10 shown in FIG. 1.

Note that the above description illustrates the semiconductor device 10 having the parasitic capacitance reducing structures Rpc formed in the respective side surfaces of the element conductor 30 and the connection conductor 40 that face each other. However, the semiconductor device 10 may have a parasitic capacitance reducing structure Rpc formed only in one of the element conductor 30 and the connection conductor 40.

Further, although the shape of the element flange portion 32 in top view and the shape of the columnar portion 31 in traversal cross-sectional view are illustrated to be hexagonal, they may be polygonal other than hexagonal. The same applies to the connection conductor 40. Although the shape of the connection flange portion 42 in top view and the shape of the columnar portion 41 in traversal cross-sectional view are illustrated to be hexagonal, they may be polygonal other than hexagonal.

Further, the shape of the element flange portion 32 in top view and the shape of the columnar portion 31 in traversal cross-sectional view may have different polygonal shapes. The same applies to the connection conductor 40. The shape of the element flange portion 42 in top view and the shape of the columnar portion 41 in traversal cross-sectional view may have different polygonal shapes.

Further, although the inclined surfaces 32c, 42c constituting the parasitic capacitance reducing structures Rpc are illustrated as the linearly inclined structures, they may be curved or stepped.

According to the first embodiment of the present invention, the following advantageous effects can be obtained.

(1) The semiconductor device 10 includes: the element conductor 30 on which the semiconductor element 11 is mounted; and the connection conductor 40 having the bonding wire 12 connected to the semiconductor element 11, wherein the parasitic capacitance reducing structure Rpc is provided in at least one of the facing surfaces 32b and 42 of the element conductor 30 and the connection conductor 40 facing each other. In the first embodiment, the parasitic capacitance reducing structure Rpc is formed by the front end surface 32b of the element flange portion 32 of the element conductor 30 and the inclined surfaces 32c on both sides of the front end surface 32b. Additionally, the parasitic capacitance reducing structure Rpc is formed by the front end surface 42b of the connection flange portion 42 of the connection conductor 40 and the inclined surfaces 42c on both sides of the front end surface 42b. The area of each of the front end surface 32b of the element flange portion 32 and the front end surface 42b of the connection flange portion 42 is small, and the inclined surfaces 32c, 42c are formed on both sides of the front end surface 32b, 42b, respectively. The inter-terminal distance between the columnar portion 31 of the element conductor 30 and the columnar portion 41 of the connection conductor 40 is larger than the minimum inter-terminal distance Lmin between the front end surface 32b of the element flange portion 32 of the element conductor 30 and the front end surface 42b of the connection flange portion 42 of the connection conductor 40. Therefore, the parasitic capacitance between the element conductor 30 and the connection conductor 40 can be reduced.

(2) The parasitic capacitance reducing structure Rpc of the element conductor 30 includes the element flange portion 32 projecting from the upper part of the columnar portion 31, and the parasitic capacitance reducing structure Rpc of the connection conductor 40 includes the connection flange portion 42 projecting from the upper part of the columnar portion 41. The parasitic capacitance reducing structure Rpc having this structure has a thickness smaller than that of a structure in which the entire thickness of the element conductor 30 including the columnar portion 31 or the entire thickness of the connection conductor 40 including the columnar portion 41 constitutes a parasitic capacitance reducing structure Rpc. Therefore, the parasitic capacitance can be further reduced. Further, the inter-terminal distance between the columnar portion 31 of the element conductor 30 and the columnar portion 41 of the connection conductor 40 is larger than the minimum inter-terminal distance Lmin between the front end surface 32b of the element flange portion 32 of the element conductor 30 and the front end surface 42b of the connection flange portion 42 of the connection conductor 40. Therefore, the conductors have a structure that is difficult to be pulled out from the encapsulation resin 14 due to an anchor effect. Additionally, the amount of the encapsulation resin 14 filled between the terminals of the columnar portion 31 of the element conductor 30 and of the columnar portion 41 of the connection conductor 40 is increased so that occurrence of cracks of the encapsulation resin 14 in this region can be reduced.

(3) In top view, the area of the element mounting surface 32a of the element conductor 30 is formed smaller than the area (base area) of the semiconductor element 11, and the outer peripheral side surface of the semiconductor element 11 is located outside the outer peripheral side surface of the element mounting surface 32a. By setting the size of the element mounting surface 32a of the element conductor 30 to be smaller than the size of the semiconductor element 11 in this way, the size of the semiconductor device 10 can be reduced.

### Second Embodiment

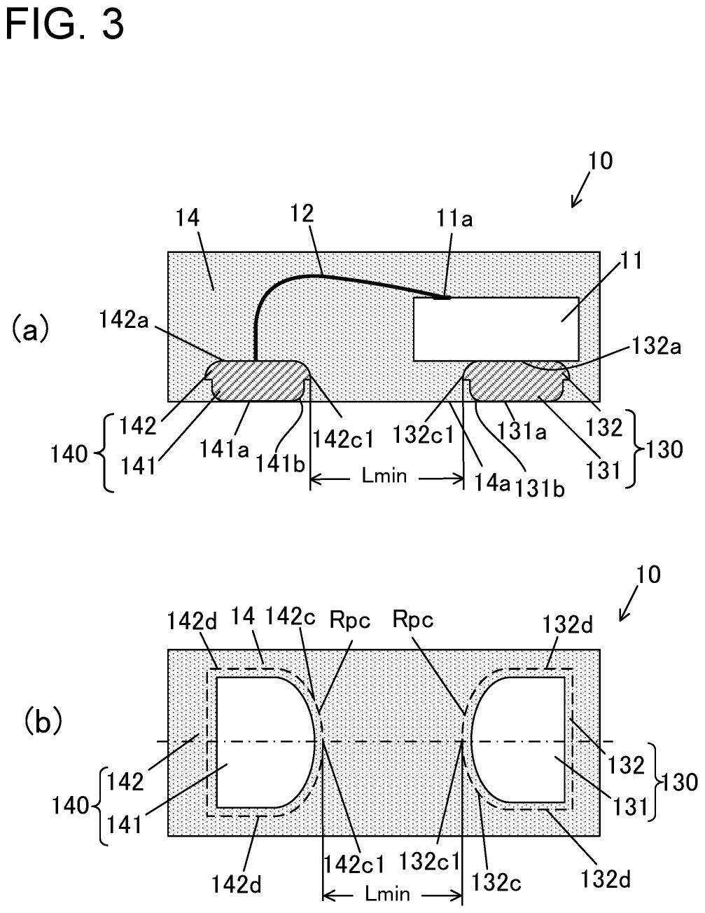

FIG. 3 shows a second embodiment of the semiconductor device according to the present invention. FIG. 3(a) is a cross-sectional view of the semiconductor device and FIG. 3(b) is a bottom view of FIG. 3(a) as viewed from below. Note that illustration of a semiconductor element 11 and a bonding wire 12 is omitted in FIG. 3(b).

The second embodiment has a parasitic capacitance reducing structure Rpc different from that of the first embodiment. However, other configurations are the same as those of the first embodiment. Therefore, the parasitic capacitance reducing structure Rpc of the second embodiment will be mainly described below.

Also in the second embodiment, an element conductor 130 has a columnar portion 131 and an element flange portion 132 provided in a shape projecting from the columnar portion 131, and a connection conductor 140 has a columnar portion 141 and a connection flange portion 142 provided in a shape projecting from the columnar portion 141. Further, in similar to the first embodiment, the semiconductor element 11 is mounted on an element mounting surface 132a of the element flange portion 132 of the element conductor 130, and a bonding wire 12 is bonded to a bonding surface 142a of the connection flange portion 142 of the connection conductor 140.

A lower surface 131a of the columnar portion 131 of the element conductor 130 and a lower surface 141a of the columnar portion 141 of the connection conductor 140 are substantially flush with a lower surface 14a of an encapsulation resin 14 so that the lower surfaces 131a, 141a are exposed from the lower surface 14a of the encapsulation resin 14.

As shown in FIG. 3(a), in the columnar portions 131, 141 of the element conductors 130, 140, outer peripheral edges 131b, 141b on the lower surface side exposed from the encapsulation resin 14 are contoured in an arc shape in cross section.

Additionally, as shown in FIG. 3(b), a side surface of the element flange portion 132 of the element conductor 130 facing the connection conductor 140 is formed as a curved surface 132c that is curved in an arc shape in plan view. In the curved surface 132c, a generally central portion 132c1 of a pair of side surfaces 132d of the element conductor 130 is arranged closest to the connection conductor 140. Similarly, a side surface of the connection flange portion 142 of the connection conductor 140 facing the element conductor 130 is formed as a curved surface 142c that is curved in an arc shape in plan view. In the curved surface 142c, a generally central portion 142c1 of a pair of side surfaces 142d of the connection conductor 140 is arranged closest to the element conductor 130. Therefore, an inter-terminal distance between the central portion 132c1 of the curved surface 132c and the central portion 142c1 of the curved surface 142c is the minimum inter-terminal distance Lmin, which is the smallest among inter-terminal distances between the element conductor 130 and the connection conductor 140.

Note that, although the curved surfaces 132c, 142c are in an arc shape in plan view, the term “arc shape” includes arc shapes such as an ellipse, a parabola, and an exponential curve, in addition to a perfect circle.

As shown in FIG. 3(b), the inter-terminal distance between the element conductor 130 and the connection conductor 140 increases gradually with an increase in a distance from the central portion 132c1 of the curved surface 132c and from the central portion 142c1 of the curved surface 142c in the up-down direction of FIG. 3. Therefore, in the semiconductor device 10 of the second embodiment, a parasitic capacitance between the element conductor 130 and the connection conductor 140 is smaller than the parasitic capacitance of the structure in the above-mentioned comparative example in which the facing side surfaces of the element conductor 130 and the connection conductor 140 extend with a constant distance from each other (the minimum inter-terminal distance Lmin) across the whole width thereof. In the second embodiment, the curved surface 132c of the element flange portion 32, which is the side surface of the element conductor 130 facing the connection conductor 40, constitutes a parasitic capacitance reducing structure Rpc. Similarly, the curved surface 142c, which is the side surface of the connection conductor 140 facing the element conductor 130, constitutes a parasitic capacitance reducing structure Rpc.

A method of manufacturing the semiconductor device 10 of the second embodiment is the same as the method of manufacturing the semiconductor device 10 of the first embodiment, except for a step of forming the outer peripheral edges 131b, 141b in which the columnar portion 131 of the element conductor 130 and the columnar portion 141 of the connection conductor 140 are contoured on their lower end sides.

Therefore, the step of forming the outer peripheral edge 131b of the element conductor 130 and the outer peripheral edge 141b of the connection conductor 140 will be described below.

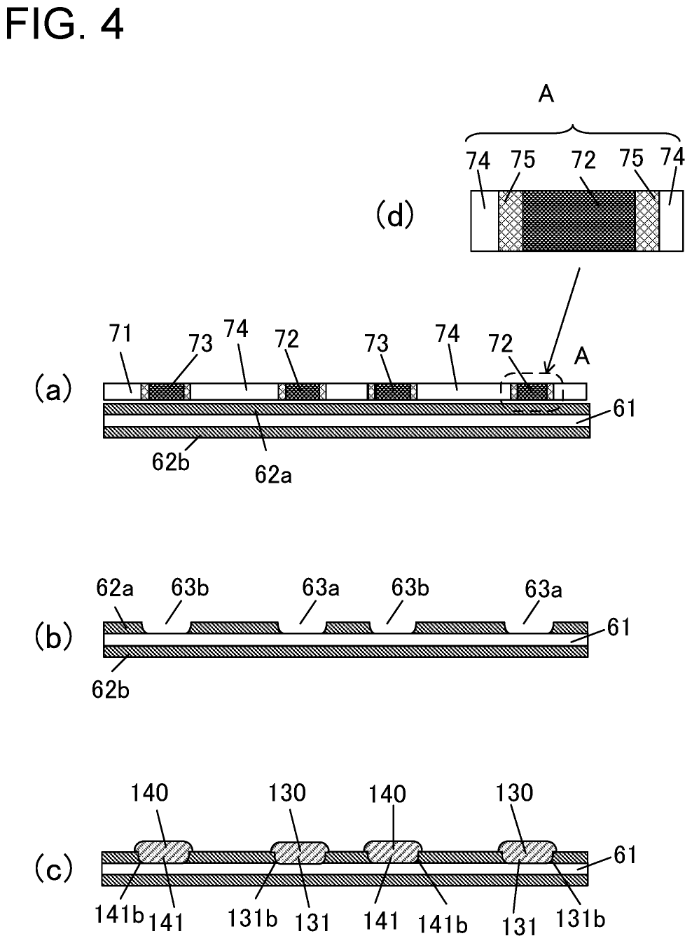

FIG. 4 is a view for illustrating a method of manufacturing the semiconductor device shown in FIG. 3. FIGS. 4(a) to 4(c) are cross-sectional views of members in each step. FIG. 4(d) is an enlarged view of a region A in FIG. 4(a).

As shown in FIG. 4(a), a substrate 61 is prepared and photoresist films 62a, 62b are formed on both front and back surfaces of the substrate 61. Although the photoresist films 62a, 62b may be of positive type or negative type, a case of using negative-type films will be described in the following description.

A glass substrate 71 serving as a mask is arranged on the photoresist film 62a. In the glass substrate 71, a light-shielding region 72 having the same shape as that of the columnar portion 131 of the element conductor 130 and a light-shielding region 73 having the same shape as that of the columnar portion 141 of the connection conductor 140 are formed. The step of forming the element conductor 130 and the step of forming the connection conductor 140 are the same. Hereinafter, the step of forming the element conductor 130 will be described as a representative example.

FIG. 4(d) is an enlarged view of a region A in FIG. 4(a).

The light-shielding region 72 of the glass substrate 71 having the same shape as that of the columnar portion 131 of the element conductor 130 is a 100% light-shielding region. In the glass substrate 71, a light-transmitting region 74 having a light-transmitting rate of approximately 100% (i.e., a light-shielding rate of approximately 0%) is provided between the element flange portion 132 of the element conductor 130 and the connection flange portion 142 of the connection conductor 140. An intermediate light-shielding region 75 is provided between the light-shielding region 72 and the light-transmitting region 74. The intermediate light-shielding region 75 is formed by arranging light-shielding films spaced one another in a dot pattern, or by making concentration and thickness of the light-shielding films smaller than those of the light-shielding region 72. However, a change rate of the light-shielding rate in the intermediate light-shielding region 75 is set so that the change rate of the light-shielding rate near the light-transmitting region 74 is larger than the change rate of the light-shielding rate near the light-shielding region 72. A light-shielding rate in a boundary portion where the intermediate light-shielding region 75 contacts the light-shielding region 72 is the largest.

When exposed with such a glass substrate 71 as a mask, a portion to be cured in the photoresist film 62a corresponding to the intermediate light-shielding region 75 gradually increases from the light-shielding region 72 toward the light-transmitting region 74 between the light-shielding region 72 and the light-transmitting region 74.

Therefore, once the photoresist film 62a is developed, openings 63a, 63b are formed, each of which gently descends toward the inner side on the lower surface 131a side of the columnar portion 131 of the element conductor 130 (see FIG. 4(c)) and on the lower surface 141a side (see FIG. 4(c)) of the columnar portion 141 of the connection conductor 140, as shown in FIG. 4(b).

Therefore, next, when a plating layer having a thickness larger than that of the photoresist film 62a is formed by electroforming or the like, the element conductor 130 and the connection conductor 140 are formed with the contoured outer peripheral edges 131b, 141b formed in the lower surface sides of the columnar portions 131, 141, respectively, as shown in FIG. 4(c).

Thereafter, the semiconductor device 10 shown in FIG. 3 can be obtained by following the steps shown in FIGS. 2(d), 2(e) of the first embodiment.

Also in the second embodiment, each of the element conductor 130 and the connection conductor 140 has a parasitic capacitance reducing structure Rpc. Additionally, the parasitic capacitance reducing structures Rpc of the element conductor 130 and the connection conductor 140 are provided in the element flange portion 132 and the connection flange portion 142, respectively, that have outer peripheral surfaces larger than the outer peripheral surfaces of the columnar portions 131, 141. Further, in top view, an area of the element mounting surface 132a of the element conductor 130 is formed smaller than an area of the semiconductor element 11, and the outer peripheral side surface of the semiconductor element 11 is located outside an outer peripheral side surface of the element mounting surface 132a. Note that the outer peripheral side surface of the semiconductor element 11 may be flush with the outer peripheral side surface of the element mounting surface 132a of the element conductor 130. Alternatively, the outer peripheral side surface of the semiconductor element 11 may be located inside the outer peripheral side surface of the element mounting surface 132a of the element conductor 130.

Thus, also in the second embodiment, the same advantageous effects as the effects (1) to (3) of the first embodiment can be obtained.

### Third Embodiment

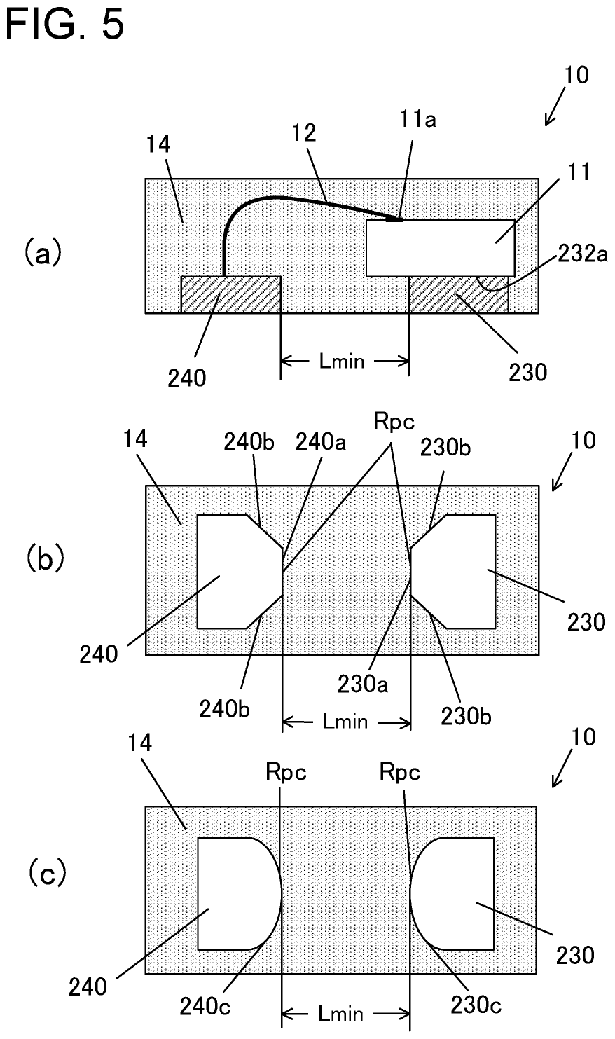

FIG. 5 shows a third embodiment of the semiconductor device according to the present invention. FIG. 5(a) is a cross-sectional view of the semiconductor device, FIG. 5(b) is a first bottom view of FIG. 5(a) as viewed from below, and FIG. 5(c) is a second bottom view of FIG. 5(a) as viewed from below.

In a semiconductor device 10 of the third embodiment, as shown in FIG. 5(a), an element conductor 230 and a connection conductor 240 each have no flange portion and have a columnar structure as a whole.

As shown in FIG. 5(b), a lower surface of each of the element conductor 230 and the connection conductor 240, respectively, has a polygonal shape having a front end surface 230a, 240a and a pair of inclined surfaces 230b, 240b, in the same manner as in the first embodiment.

The inclined surfaces 230b on both sides of the front end surface 230a in the element conductor 230 constitute a parasitic capacitance reducing structure Rpc. Additionally, the inclined surfaces 240b on both sides of the front end surface 240a in the connection conductor 240 constitute a parasitic capacitance reducing structure Rpc.

As shown in FIG. 5(c), the element conductor 230 and the connection conductor 240 may have structures in which their side surfaces facing each other have curved surfaces 230c, 240c that are curved in an arc shape, in the manner similar to the element flange portion 132 and the connection flange portion 142 of the second embodiment. In this structure, each of the curved surface 230c of the element conductor 230 and the curved surface 240c of the connection conductor 240 constitutes a parasitic capacitance reducing structure Rpc.

Other configurations of the third embodiment are similar to those of the first embodiment, and corresponding members are thus designated by the same reference numerals and description thereof will be omitted.

Also in the third embodiment, the element conductor 230 and the connection conductor 240 each have the parasitic capacitance reducing structure Rpc. Further, in top view, an area of the element conductor 230 is formed smaller than an area of the semiconductor element 11, and the outer peripheral side surface of the semiconductor element 11 is located outside an outer peripheral side surface of the element conductor 230. Alternatively, the outer peripheral side surface of the semiconductor element 11 may be flush with the outer peripheral side surface of an element mounting surface 232a of the element conductor 230. Alternatively, the outer peripheral side surface of the semiconductor element 11 may be located inside the outer peripheral side surface of the element mounting surface 232a of the element conductor 230.

Thus, in the third embodiment, the same advantageous effects as the effects (1) and (3) of the first embodiment can be obtained.

### Fourth Embodiment

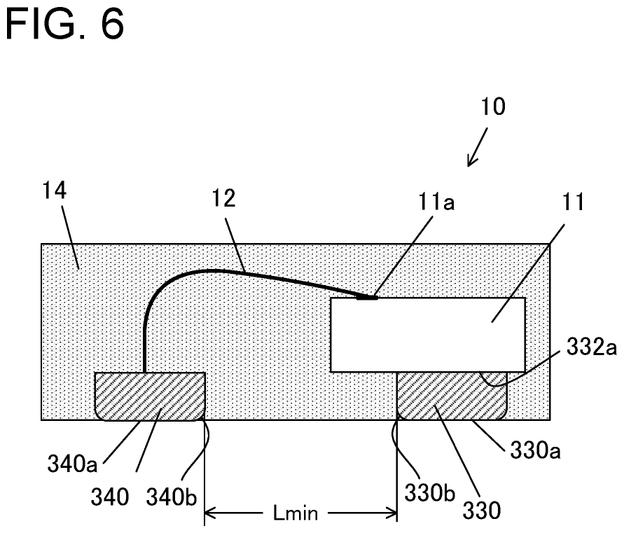

FIG. 6 is a cross-sectional view showing a fourth embodiment of the semiconductor device according to the present invention.

In a semiconductor device 10 of the fourth embodiment, an element conductor 330 and a connection conductor 340 each have no flange portion and have a columnar structure as a whole, in the same manner as in the third embodiment. The semiconductor device 10 of the fourth embodiment is different from the semiconductor device 10 of the third embodiment in that the element conductor 330 and the connection conductor 340 have outer peripheral edges 330b, 340b that are contoured on lower surface 330a, 340a side, respectively.

Also in the semiconductor device 10 of the fourth embodiment, each of the element conductor 330 and the connection conductor 340 has a parasitic capacitance reducing structure Rpc. Further, in top view, an area of the element conductor 330 is formed smaller than an area of the semiconductor element 11, and the outer peripheral side surface of the semiconductor element 11 is located outside an outer peripheral side surface of the element conductor 330. Alternatively, the outer peripheral side surface of the semiconductor element 11 may be flush with the outer peripheral side surface of the element mounting surface 332a of the element conductor 330. Alternatively, the outer peripheral side surface of the semiconductor element 11 may be located inside the outer peripheral side surface of an element mounting surface 332a of the element conductor 330.

Thus, the same advantageous effects as the effects (1) and (3) of the first embodiment can be obtained.

### Fifth Embodiment

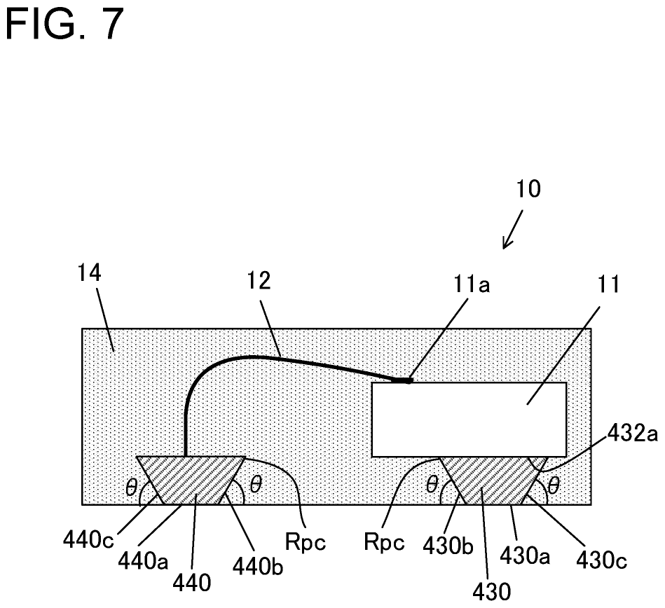

FIG. 7 is a cross-sectional view showing a fifth embodiment of the semiconductor device according to the present invention.

In a semiconductor device 10 of the fifth embodiment, an element conductor 430 and a connection conductor 440 each have no flange portion, in the same manner as in the third and fourth embodiments, and have an inverted trapezoidal shape in cross section.

That is, the element conductor 430 has a tapered surface 430b that gradually ascends from a lower surface 430a toward the connection conductor 440 side, and a tapered surface 430c that gradually ascends from the lower surface 430a in a direction opposite to the connection conductor 440 side. In other words, the element conductor 430 has the tapered surface 430b such that a distance of the tapered surface 430b from the connection conductor 440 increases in a direction away from the semiconductor element 11. Similarly, the connection conductor 440 has a tapered surface 440b that gradually ascends from a lower surface 440a toward the element conductor 430 side, and a tapered surface 440c that gradually ascends from the lower surface 430a in a direction opposite to the element conductor 430 side. In other words, the connection conductor 440 has the tapered surface 440b such that a distance of the tapered surface 440b from the element conductor 430 increases in a direction away from the bonding surface.

That is, the element conductor 430 and the connection conductor 440 have the inclined surfaces 430b, 440b facing each other. In FIG. 7, the inclined surfaces 430b, 440b are inclined surfaces that flare from the conductor lower surfaces 430a, 440a upward in the figure, that is, toward the semiconductor mounting surface (element mounting surface 432a) and the bonding surface. Assuming that a spacing between a pair of facing sides (sides extending in the depth direction of the paper plane of FIG. 7), where the semiconductor mounting surface and the bonding surface face each other, corresponds to the minimum inter-terminal distance Lmin of the comparative structure, a distance between the inclined surfaces 430b, 440b gradually increases along the direction from the semiconductor mounting surface and the bonding surface toward the respective lower surfaces 430a, 440a. Therefore, the parasitic capacitance between the element conductor 430 and the connection conductor 440 is smaller than that in the comparative structure.

The element conductor 430 and the connection conductor 440 having the inclined surfaces 430b, 440b that constitute the parasitic capacitance reducing structures Rpc in the fifth embodiment have a tapered polygonal shape shown in FIG. 5(b) or a curved surface shown in FIG. 5(c).

Taper angles θ of the tapered surfaces 430b, 430c and the tapered surfaces 440b, 440c are preferably in a range of 30° to 60° with respect to the lower surface 14a of the encapsulation resin 14. In a case where the taper angle θ is larger than approximately 60°, a pullout force from the encapsulation resin 14 tends to be smaller. In a case where the taper angle θ is smaller than approximately 30°, it is difficult for the encapsulation resin material to flow into the lower surface sides of the tapered surfaces 430b, 430c of the element conductor 430 and the tapered surfaces 440b, 440c of the connection conductor 440 when the encapsulation resin 14 is formed by molding. This is likely to occur cracks in the encapsulation resin 14.

The method according to the second embodiment may be applied as a method of manufacturing the element conductor 430 having the tapered surfaces 430b, 430c and the connection conductor 440 having the tapered surfaces 440b, 440c. However, in order to form the element conductor 430 having the linearly inclined tapered surfaces 430b, 430c or the connection conductor 440 having the linearly inclined tapered surfaces 440b, 440c, a change rate in the light-shielding rate of the intermediate light-shielding region 75 of the glass substrate 71 is uniformly set from the intermediate light-shielding region 75 side to the light-transmitting region 74 side.

Note that in the fifth embodiment, the tapered surface 430c of the element conductor 430 and the tapered surface 440c of the connection conductor 440 may have a taper angle θ=90°; in other words, the surfaces may not be tapered.

Further, the element conductor 430 and the connection conductor 440 may each have a flange portion having a tapered surface 430b, 440b and a columnar portion provided under the flange portion. That is, the tapered surface 430b may be formed from the upper surface 432a of the element conductor 430 to the middle position of the thickness, and a surface having the taper angle θ=90° may be formed from the middle position to the lower surface 430a. Further, the tapered surface 440b may be formed from the upper surface of the connection conductor 440 to the middle position of the thickness, and a surface having the taper angle θ=90° may be formed from the middle position to the lower surface 440a.

Other configurations of the fifth embodiment are similar to those of the first embodiment, and corresponding members are thus designated by the same reference numerals and description thereof will be omitted.

Also in the fifth embodiment, each of the element conductor 430 and the connection conductor 440 has a parasitic capacitance reducing structure Rpc. Further, in top view, an area of the element conductor 430 is formed smaller than an area of the semiconductor element 11, and the outer peripheral side surface of the semiconductor element 11 is located outside an outer peripheral side surface of the element conductor 430.

Thus, in the fifth embodiment, the same advantageous effects as the effects (1) and (3) of the first embodiment can be obtained.

Additionally, in the fifth embodiment, the same advantageous effect as the effect (2) of the first embodiment can be obtained when the element conductor 430 and the connection conductor 440 each include a flange portion and a columnar portion provided under the flange portion.

Note that, in the fifth embodiment, the outer peripheral side surface of the semiconductor element 11 may be flush with the outer peripheral side surface of the element mounting surface 432a of the element conductor 430. Alternatively, the outer peripheral side surface of the semiconductor element 11 may be located inside the outer peripheral side surface of the element mounting surface 432a of the element conductor 430.

### Sixth Embodiment

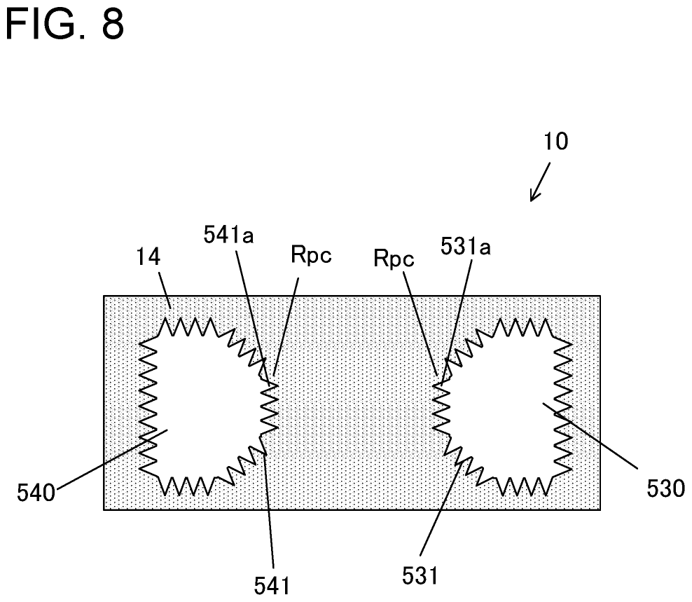

FIG. 8 shows a sixth embodiment of the semiconductor device according to the present invention and is a bottom view of the semiconductor device as viewed from bottom surface side.

Each of an element conductor 530 and a connection conductor 540 shown in FIG. 8 has a plurality of fine irregularities 531a, 541a continuously formed in outer peripheral side surfaces 531, 541, respectively. Each of the element conductor 530 and the connection conductor 540 has the fine irregularities 531a, 541a formed continuously in the outer peripheral side surface of a tapered portion or in the outer peripheral side surface including a curved surface in top view, respectively, as shown in FIG. 5(b) or 5(c). Facing regions of the outer peripheral side surface 531 of the element conductor 530 and the outer peripheral side surface 541 of the connection conductor 540, in which the fine irregularities 531a, 541a are formed, constitute parasitic capacitance reducing structures Rpc.

Areas of the outer peripheral side surfaces 531, 541 are increased by providing the fine irregularities 531a in the outer peripheral side surface 531 of the element conductor 530 and providing the fine irregularities 541a in the outer peripheral side surface 541 of the connection conductor 540. As a result, an adhesive force (bonding strength) between the encapsulation resin 14, and the element conductor 530 and the connection conductor 540 is increased.

Note that, in FIG. 8, each of the fine irregularities 531a, 541a is illustrated to have a relatively large size for ease of understanding of the shape, but its actual size is preferably smaller than the illustrated size. Further, the fine irregularities 531a and 541a are illustrated as having sharp tip portions, but the tip portions may be rounded to reduce electric field concentration on the tip portion.

The element conductor 530 and the connection conductor 540 can be manufactured by the same method as that of the first embodiment, by shaping mask patterns of the element conductor 530 and the connection conductor 540 such that fine irregularities 531a, 541a are to be formed in the outer peripheral side surfaces 531, 541, respectively.

Each of the element conductor 530 and the connection conductor 540 may have a columnar structure as a whole, or a structure including a flange portion having fine irregularities 531a, 541a and a columnar portion provided under the flange portion. Other configurations of the sixth embodiment are similar to those of the first embodiment.

Also in the sixth embodiment, each of the element conductor 530 and the connection conductor 540 has a parasitic capacitance reducing structure Rpc. Further, in top view, an area of the element conductor 530 is formed smaller than an area of the semiconductor element 11, and the outer peripheral side surface of the semiconductor element 11 is located outside an outer peripheral side surface of the element conductor 530.

Thus, in the sixth embodiment, the same advantageous effects as the effects (1) and (3) of the first embodiment can be obtained.

Additionally, in the sixth embodiment, the same advantageous effect as the effect (2) of the first embodiment can be obtained when the element conductor 530 and the connection conductor 540 each include a flange portion having the fine irregularities 531a, 541a and a columnar portion provided under the flange portion.

Note that in the sixth embodiment, in top view, sides (lines) corresponding to the outer peripheral side surface of the semiconductor element 11 may coincide with lines connecting protrusion tips of irregularities 531a formed in the outer peripheral side surface of an element mounting surface (not shown) of the element conductor 530. Note that, in top view, sides (lines) corresponding to the outer peripheral side surface of the semiconductor element 11 may be located inside lines connecting protrusion tips of irregularities 531a formed in the outer peripheral side surface of the element mounting surface (not shown) of the element conductor 530.

### Seventh Embodiment

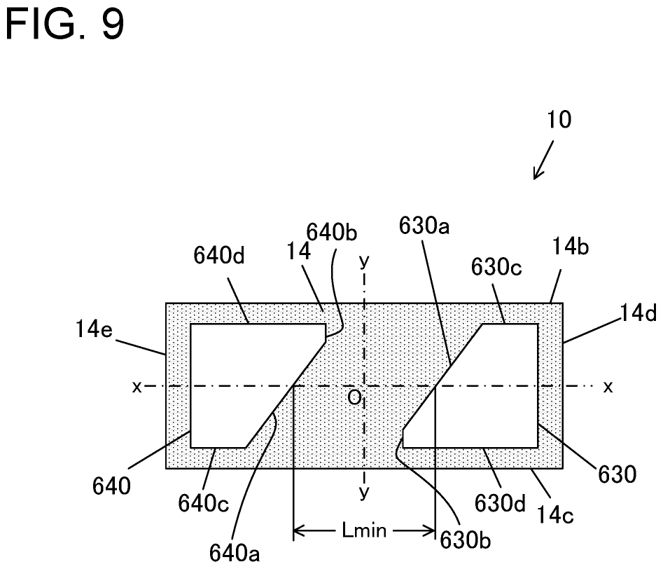

FIG. 9 shows a seventh embodiment of the semiconductor device according to the present invention and is a bottom view of the semiconductor device as seen from below.

In a semiconductor device 10 of the seventh embodiment, an element conductor 630 and a connection conductor 640 are arranged point-symmetrically with respect to an intersection O of a center line x-x passing through the center between a pair of long sides 14b, 14c of the encapsulation resin 14 and a center line y-y passing through the center between a pair of short sides 14d, 14e of the encapsulation resin 14.

The element conductor 630 has an inclined surface 630a provided on the connection conductor 640 side, a vertical end surface 630b, and a pair of side surfaces 630c, 630d. The connection conductor 640 has an inclined surface 640a facing the element conductor 630, a vertical end surface 640b, and a pair of side surfaces 640c, 640d.

The inclined surface 630a of the element conductor 630 and the inclined surface 640a of the connection conductor 640 are parallel to each other. Therefore, an inter-terminal distance between the inclined surface 630a of the element conductor 630 and the inclined surface 640a of the connection conductor 640 is the minimum inter-terminal distance Lmin across the whole surface region.

The inclined surface 630a of the element conductor 630 and the inclined surface 640a of the connection conductor 640 extend over substantially the whole length in the width direction (in the up-down direction in FIG. 9). However, each of the inclined surface 630a of the element conductor 630 and the inclined surface 640a of the connection conductor 640 is inclined with respect to the center line y-y. Therefore, a parasitic capacitance between the element conductor 630 and the connection conductor 640 is smaller than the parasitic capacitance of the above-described comparative structure formed between the conductors (parallel plates) that are parallel to the center line y-y and are spaced by the minimum inter-terminal distance Lmin. That is, each of the inclined surface 630a of the element conductor 630 and the inclined surface 640a of the connection conductor 640 constitutes a parasitic capacitance reducing structure Rpc.

Note that the end surface 630b of the element conductor 630 and the end surface 640b of the connection conductor 640 are intended to reduce electric field concentration. That is, if an intersection of the inclined surface 630a and the side surface 630d of the element conductor 630 is made sharp, electric field concentration occurs at this intersection. Further, if an intersection of the inclined surface 640a and the side surface 640d of the element conductor 640 is made sharp, electric field concentration occurs at this intersection. The end surface 630b of the element conductor 630 and the end surface 640b of the connection conductor 640 reduce such electric field concentration.

In the seventh embodiment, each of the element conductor 630 and the connection conductor 640 may have a columnar structure as a whole, or a structure including a flange portion having the inclined surfaces 630a, 640a and a columnar portion provided under the flange portion.

Other configurations of the seventh embodiment are similar to those of the first embodiment.

Also in the seventh embodiment, each of the element conductor 630 and the connection conductor 640 has a parasitic capacitance reducing structure Rpc. Although not shown, in top view, the outer peripheral side surface of the semiconductor element 11 is located outside an outer peripheral side surface of the element conductor 630.

Thus, in the seventh embodiment, the same advantageous effects as the effects (1) and (3) of the first embodiment can be obtained.

Additionally, in the seventh embodiment, the same advantageous effect as the effect (2) of the first embodiment can be obtained when the element conductor 630 and the connection conductor 640 each include a flange portion having the inclined surface 630a, 640a and a columnar portion provided under the flange portion.

Alternatively, in the seventh embodiment, in top view, the outer peripheral side surface of the semiconductor element 11 may be located inside the outer peripheral side surface of the element conductor 630.

### Eighth Embodiment

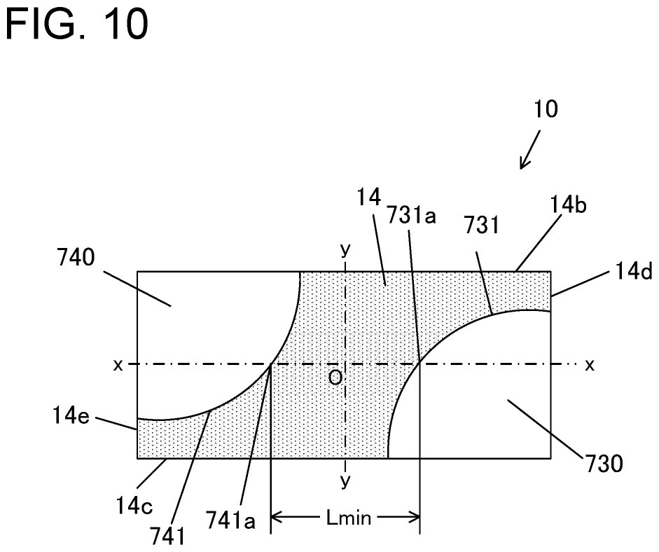

FIG. 10 shows an eighth embodiment of the semiconductor device according to the present invention and is a bottom view of the semiconductor device as viewed from below.

In the semiconductor device 10 of the eighth embodiment, an element conductor 730 and a connection conductor 740 are fan-shaped in plan view. The element conductor 730 has an outer peripheral side surface 731 in a shape of an arc that is a part of a circle centered on an intersection of one long side 14c and one short side 14d of the encapsulation resin 14. The connection conductor 740 has an outer peripheral side surface 741 in a shape of an arc that is a part of a circle centered on an intersection of the other long side 14b and the other short side 14e. The element conductor 730 and the connection conductor 740 are arranged point-symmetrically with respect to an intersection O of a center line x-x passing through the center between a pair of the long sides 14b, 14c of the encapsulation resin 14 in the width direction and a center line y-y passing through the center between a pair of the short sides 14d, 14e of the encapsulation resin 14.

In FIG. 10, a distance between a point 731a in the outer peripheral side surface 731 of the element conductor 730 and a point 741a in the outer peripheral side surface 741 of the connection conductor 740 is the minimum inter-terminal distance Lmin. An inter-terminal distance between the outer peripheral side surface 731 of the element conductor 730 and the outer peripheral side surface 741 of the connection conductor 740 increases in accordance with a length of separation from the point 731a or the point 741a. Therefore, each of the outer peripheral side surface 731 of the element conductor 730 and the outer peripheral side surface 741 of the connection conductor 740 constitutes a parasitic capacitance reducing structure Rpc.

In the eighth embodiment, each of the element conductor 730 and the connection conductor 740 may have a columnar structure as a whole, or a structure including a flange portion having the arc-shaped outer side surface 731, 741 and a columnar portion provided under the flange portion.

Other configurations in the eighth embodiment are similar to those in the first embodiment.

Also in the eighth embodiment, each of the element conductor 730 and the connection conductor 740 has a parasitic capacitance reducing structure Rpc. Although not shown, in top view, the outer peripheral side surface of the semiconductor element 11 is located outside an outer peripheral side surface of the element conductor 730. It is preferable that the semiconductor element 11 (not shown) is also entirely covered with the encapsulation resin 14.

Thus, in the eighth embodiment, the same advantageous effects as the effects (1) and (3) of the first embodiment can be obtained.

Additionally, in the eighth embodiment, the same advantageous effect as the effect (2) of the first embodiment can be obtained when the element conductor 730 and the connection conductor 740 each include a flange portion having the arc-shaped outer peripheral side surface 731, 741 and a columnar portion provided under the flange portion.

Alternatively, in the eighth embodiment, in top view, the outer peripheral side surface of the semiconductor element 11 may be located inside the outer peripheral side surface of the element conductor 730.

### Ninth Embodiment

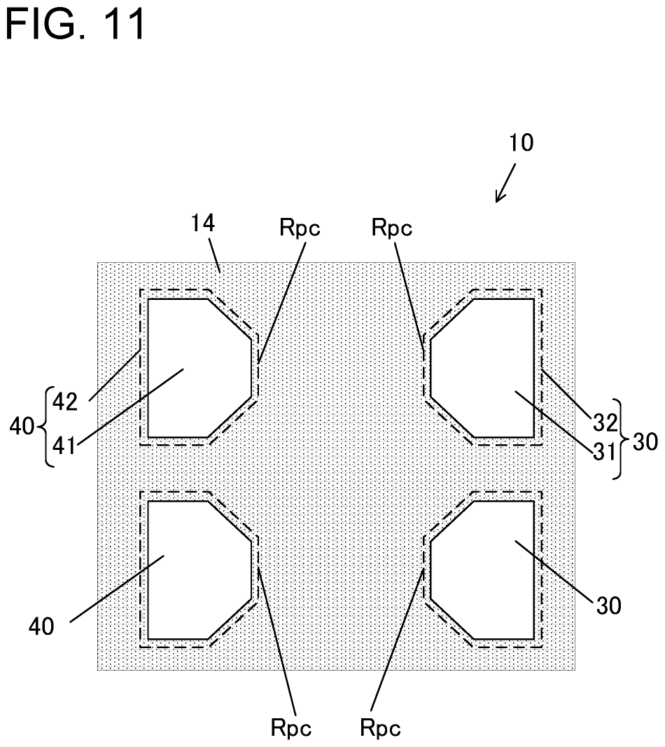

FIG. 11 shows a ninth embodiment of the semiconductor device according to the present invention and is a bottom view of the semiconductor device as viewed from below.

A semiconductor device 10 of the ninth embodiment has a plurality of sets (illustrated as two sets in FIG. 11) of the element conductor 30 and the connection conductor 40 shown in the first embodiment. In this way, a plurality of sets of element conductor 30 and connection conductor 40 can be packaged with the encapsulation resin 14.

In order to manufacture the semiconductor device 10 having the plurality of sets of the element conductor 30 and the connection conductor 40, the steps of FIGS. 2(a) to 2(d) are performed in the same method as that of the first embodiment. Thereafter, in a step of cutting the encapsulation resin 14 in FIG. 2(e), the encapsulation resin 14 may be cut so that the plurality of sets of the element conductor 30 and the connection conductor 40 form one package.

FIG. 11 illustrates the semiconductor device 10 including the element conductors 30 and the connection conductors 40 shown in the first embodiment. However, the semiconductor device 10 may have a plurality of sets of the element conductor 130 to 730 and the connection conductor 140 to 740 illustrated in the second to eighth embodiments.

Because the semiconductor device 10 of the ninth embodiment may have a plurality of sets of the element conductor 30 to 730 and the connection conductor 40 to 740 illustrated in the first to eighth embodiments, the same advantageous effects as the effects (1) to (3) of the first embodiment can be obtained as a matter of course.

### Tenth Embodiment

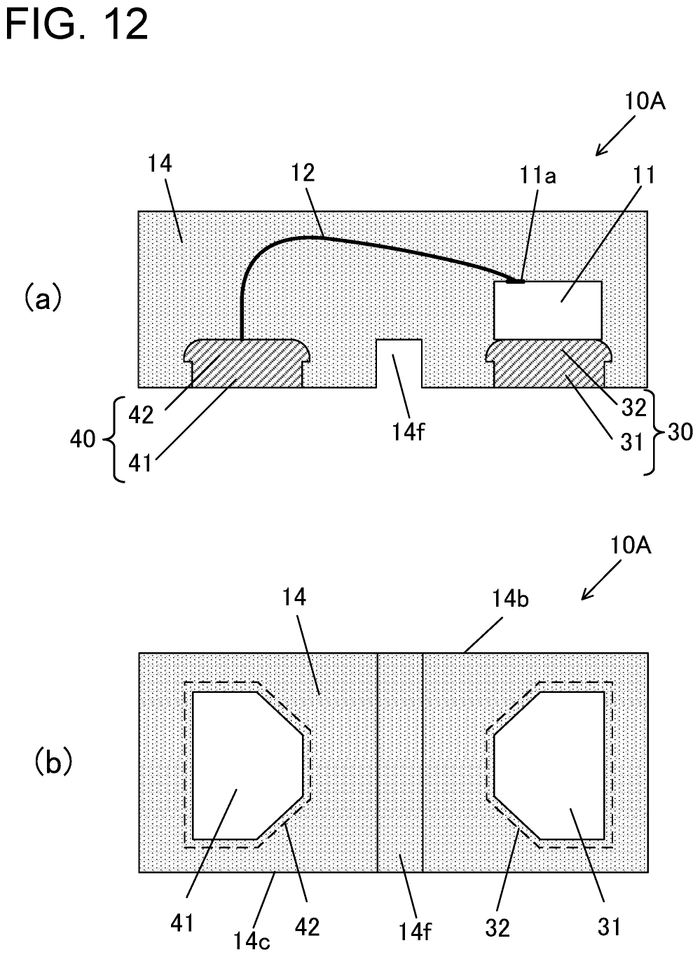

FIG. 12 shows a tenth embodiment of the semiconductor device according to the present invention. FIG. 12(a) is a cross-sectional view of the semiconductor device and FIG. 12(b) is a bottom view of FIG. 12(a) as viewed from below.

In a semiconductor device 10A of the tenth embodiment, an encapsulation resin 14 has a groove 14f formed between an element conductor 30 and a connection conductor 40. The groove 14f extends over the whole length of the encapsulation resin 14 in the width direction (in the up-down direction in FIG. 12(b)). In other words, the groove 14f is formed so as to penetrate the encapsulation resin 14 in the width direction from one long side 14b to the other long side 14c of the encapsulation resin 14.

A depth of the groove 14f is approximately the same as a thickness of the element conductor 30 and of the connection conductor 40. As long as enough strength of the encapsulation resin 14 can be ensured, the depth of the groove 14f may be made larger than the thickness of the element conductor 30 and of the connection conductor 40. In order to make the strength of the encapsulation resin 14 uniform, the groove 14f is preferably located at the center between the element conductor 30 and the connection conductor 40. However, the position of the groove 14f is not limited to the center between the element conductor 30 and the connection conductor 40. The position may be anywhere as long as it is between the element conductor 30 and the connection conductor 40.

Note that, in FIG. 12, the semiconductor element 11 mounted on the element conductor 30 is illustrated to have a size smaller than that of the element conductor 30 so that the semiconductor element 11 is located inside the outer peripheral side surface of the element conductor 30.

By forming the groove 14f between the element conductor 30 and the connection conductor 40 of the encapsulation resin 14, a parasitic capacitance of the element conductor 30 and the connection conductor 40 can be reduced.

Other configurations of the semiconductor device 10A are similar to those of the first embodiment, and corresponding members are thus designated by the same reference numerals and description thereof will be omitted.

Note that FIG. 12 illustrates the semiconductor device 10A including the element conductor 30 and the connection conductor 40 shown in the first embodiment. However, the semiconductor device 10A having any of the element conductors 130 to 730 and any of the connection conductors 140 to 740 illustrated in the second to eighth embodiments may be used.

Note that, in each of the above embodiments, the thickness of the element conductor 30 and the thickness of the connection conductor 40 are the same. However, the element conductor 30 and the connection conductor 40 may have different thicknesses.

Each embodiment described above illustrates a structure in which the semiconductor element 11 has one electrode pad 11a that is connected to one connection conductor 40 to 740 by one bonding wire 12. However, the present invention may be applied to a semiconductor device in which the semiconductor element 11 has a plurality of electrode pads 11a, and the plurality of electrode pads 11a and the same number of connection conductors 40 to 740 may be bonded via bonding wires (connection wires) 12.

In each of the above embodiments, the element conductors 30 to 730 and the connection conductors 40 to 740 have been described as electroformed layers. It is preferable to make the conductors from the plating layers because the conductor thickness can be reduced to approximately half when compared with the conductor thickness in the case of using lead frames, so that the parasitic capacitance can be reduced due to the reduced cross-sectional area. However, the element conductors 30 to 730 and the connection conductors 40 to 740 may be made from lead frames. In a case of making from lead frames, plate-like frames can be formed by etching or punching. In forming by punching, the element flange portion 32, the connection flange portion 42, and the outer peripheral edges 131b, 141b, 330b, 340b may be formed by pressing the lead frames after punching.

The structures illustrated in the first to tenth embodiments may be combined with each other. For example, the element conductor 30 to 730 of any one of the first to tenth embodiments and the connection conductor 40 to 740 of another one of the first to tenth embodiments may be combined. A semiconductor device 10, 10A may be configured so that a parasitic capacitance reducing structure is provided only in one of the element conductors 30 to 730 and the connection conductors 40 to 740 in the first to tenth embodiments, and the other conductor is not provided with a parasitic capacitance reducing structure.

Although various embodiments have been described above, the present invention is not limited thereto. Other aspects that are conceivable within the scope of the technical idea of the present invention are also encompassed within the scope of the present invention.

The disclosure of the following priority application is herein incorporated by reference:

Japanese Patent Application No. 2018-064569 (filed Mar. 29, 2018)

### REFERENCE SIGNS LIST

10, 10A semiconductor device

11 semiconductor element

12 bonding wire (connecting line)

14 encapsulation resin

14f groove

30, 130, 230, 330, 430, 530, 630, 730 element conductor

31, 131 columnar portion

32, 132 element flange portion

32a, 132a element mounting surface

32b front end surface (side surface)

40, 140, 240, 340, 440, 540, 640, 740 connection conductor

41, 141 columnar portion

42, 142 connection flange portion

42a, 142a bonding surface (connection surface)

42b front end surface (side surface)

132c, 142c curved surface (side surface)

230a, 240a front end surface (side surface)

230c, 240c curved surface (side surface)

430b, 440b tapered surface

531, 541 outer peripheral side surface (side surface)

531a, 541a irregularities

630a, 640a inclined surface (side surface)

731, 741 outer peripheral side surface (side)

Lmin minimum inter-terminal distance

Rpc parasitic capacitance reducing structure

1. A semiconductor device, comprising:
a semiconductor element;
an element conductor having an element mounting surface on which the semiconductor element is mounted;
a connection conductor that is arranged apart from the element conductor and has a connection surface on an upper part thereof;
a connecting line connecting the semiconductor element and the connection surface of the connection conductor; and
an encapsulation resin that encapsulates the semiconductor element, the element conductor, the connection conductor, and the connecting line, wherein:
a parasitic capacitance reducing structure is provided in at least one of facing side surfaces of the element conductor and of the connection conductor, the facing side surfaces being arranged to face each other.

2. The semiconductor device according to claim 1, wherein:
the parasitic capacitance reducing structure is provided in an upper side of at least one of the element conductor and the connection conductor.

3. The semiconductor device according to claim 2, wherein:
the parasitic capacitance reducing structure is provided in a columnar shape from the upper side to a lower surface of the at least one of the element conductor and the connection conductor.

4. The semiconductor device according to claim 1, wherein:
the parasitic capacitance reducing structure is a facing surface in which a facing-surface distance determined at a first position closest to the other conductor side is the smallest and a facing-surface distance at a second position different from the first position is larger than the facing-surface distance at the first position.

5. The semiconductor device according to claim 4, wherein:
the facing surface having the parasitic capacitance reducing structure is a planar surface or a curved surface.

6. The semiconductor device according to claim 1, wherein:
the parasitic capacitance reducing structure is a structure in which at least one of the element conductor and the connection conductor has a polygonal shape in plan view; and
the conductor having the polygonal shape has a first facing surface closest to the other conductor side and a second facing surface other than the first facing surface, and a facing-surface distance determined by the second facing surface is larger than a facing-surface distance determined by the first facing surface.

7. The semiconductor device according to claim 1, wherein:
the parasitic capacitance reducing structure is a structure in which at least one of the element conductor and the connection conductor has an arc shape in plan view; and
the conductor having the arc shape has a first facing surface that is closest to the other conductor side and determines the minimum facing-surface distance and a second facing surface that is different from the first facing surface, and a facing-surface distance determined by the second facing surface is larger than the minimum facing-surface distance.

8. The semiconductor device according to claim 6, wherein:
the parasitic capacitance reducing structure includes irregularities formed continuously in the first facing surface and the second facing surface.

9. The semiconductor device according to claim 1, wherein:
an area of the element mounting surface of the element conductor is formed smaller than an area of the semiconductor element in plan view, and an outer peripheral side surface of the semiconductor element is located outside an outer peripheral side surface of the element mounting surface.

10. A semiconductor device, comprising:
a semiconductor element;
an element conductor having an element mounting surface on which the semiconductor element is mounted;
a connection conductor that is arranged apart from the element conductor and has a connection surface on an upper part thereof;
a connecting line connecting the semiconductor element and the connection surface of the connection conductor;
an encapsulation resin that encapsulates the semiconductor element, the element conductor, the connection conductor, and the connecting line; and
a parasitic capacitance reducing structure provided in a facing side surface of at least one of the element conductor and the connection conductor arranged to face each other, the facing side surface facing the other conductor, wherein:
in the parasitic capacitance reducing structure, an area in a first position having a smallest facing-surface distance between a facing side surface of the one conductor and a facing side surface of the other conductor is smaller than a total area of the facing side surfaces of the one conductor.

11. The semiconductor device according to claim 10, wherein:
the area in the first position of the one conductor is smaller than a total area of entire facing side surfaces in a second position different from the first position.

12. A semiconductor device, comprising:
a semiconductor element;
an element conductor having an element mounting surface on which the semiconductor element is mounted;
a connection conductor that is arranged apart from the element conductor and has a connection surface on an upper part thereof;
a connecting line connecting the semiconductor element and the connection surface of the connection conductor; and
an encapsulation resin that encapsulates the semiconductor element, the element conductor, the connection conductor, and the connecting line; and
a groove formed in the encapsulation resin between facing side surfaces of the element conductor and the connection conductor.

13. The semiconductor device according to claim 1, wherein:
a groove formed in the encapsulation resin between facing side surfaces of the element conductor and the connection conductor.
